(19) United States
(12) Patent Application Publication
(10) Pub. No.: US 2007/0107253 A1
(43) Pub. Date: May 17, 2007

(54) SUBSTRATE DRYING DEVICE AND SUBSTRATE PROCESSING METHOD

(75) Inventor: Atsunori NISHIURA, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Mitsubishi Electric Corporation, Chiyoda-ku (JP)

(21) Appl. No.: 11/557,263

(22) Filed: Nov. 7, 2006

(30) Foreign Application Priority Data
Nov. 15, 2005 (JP) 2005-330062

(51) Int. Cl. B08B 3/00; F26B 3/00

(52) U.S. Cl. 34/444; 134/95.1; 134/94.1; 134/95.2; 134/95.3

(57) ABSTRACT

A substrate drying device according to an embodiment of the present invention includes: a nozzle ejecting a fluid to a substrate to be processed, wherein the substrate is moved relative to the nozzle while the nozzle is spraying the fluid to dry the substrate, a parallel component to a surface of the substrate in an ejection direction of the fluid is inclined with respect to a moving direction in which the substrate moves relative to the nozzle, and an angle between the parallel component and the moving direction is changed at a changed portion in a predetermined position of the nozzle.

### BACKGROUND OF THE INVENTION

1. Field of the Invention

The present invention relates to a substrate drying device and a substrate processing method.

2. Description of Related Art

Hitherto, there has been adopted a technique of spraying a dry gas from an air knife to a substrate to dry a substrate surface while transferring the substrate in one direction at the time of drying the substrate in a step of cleaning a glass substrate for a liquid crystal display or a semiconductor wafer in a manufacturing process of a liquid crystal display device or a semiconductor device. Such technique is disclosed in, for example, Japanese Unexamined Patent Application Publication No. 10-180205 and 8-288250.

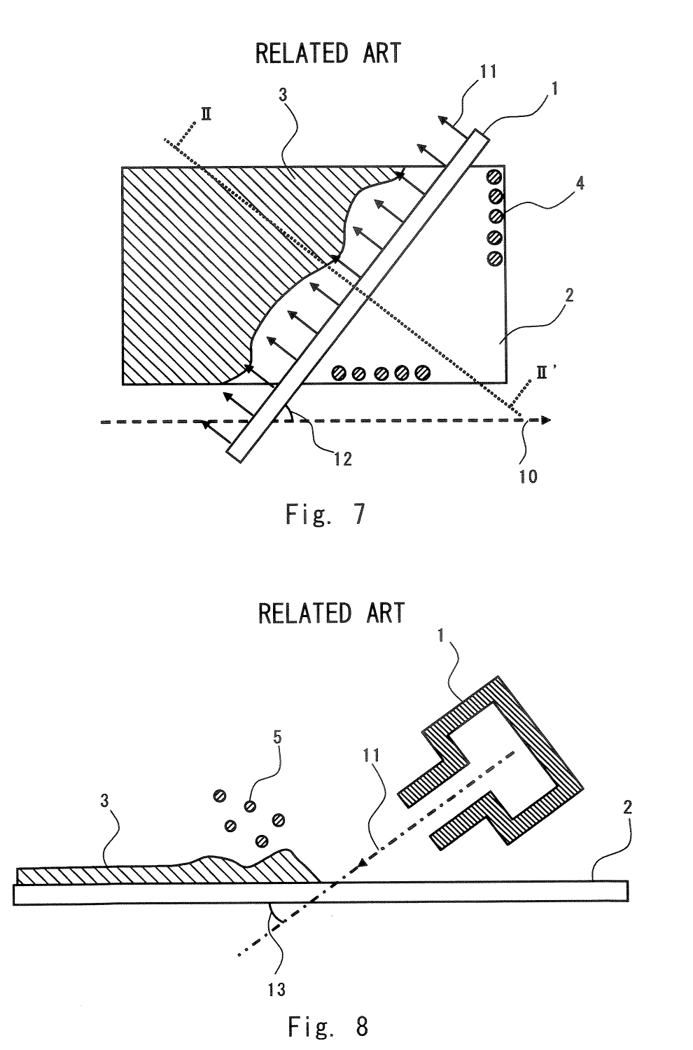

Referring to FIGS. 7 and 8, a conventional air knife drying system is described. FIG. 7 is a top view of the conventional air knife drying system, and FIG. 8 is a sectional view taken long the line II-II′ of FIG. 7. As shown in FIGS. 7 and 8, an air knife 1 is provided above the surface of a substrate 2 to spray a dry gas in an arrow 11 direction while transferring the substrate 2 in an arrow 10 direction. As a result, rinse water 3 on the substrate 2 is blown off by the dry gas sprayed from the air knife 1, and the substrate 2 surface can be dried.

Such drying system has a problem in that after the rinse water 3 is brown off, a water droplet 4 of the rinse water tends to remain at the end of the substrate 2 surface. As a solution to this problem, in the conventional system, the air knife 1 is placed at an angle 12 with respect to the transfer direction of the substrate 2, or the air knife 1 is placed at an angle 13 to the substrate 2 surface, for example. Alternatively, these countermeasures are taken in combination.

If this problem cannot be overcome with the above method of placing the air knife at the angle 12 or 13, the problem should be solved by increasing an air pressure of the dry gas sprayed from the air knife 1. However, if the air is sprayed from the air knife 1 at a too high pressure, the rinse water 3 is evaporated in the form of mist 5 in some cases, the mist 5 readheres to the substrate 2 to cause a strain. Accordingly, there is a limitation on improvements in drying efficiency by increasing a pressure of the air sprayed from the air knife 1.

### SUMMARY OF THE INVENTION

The present invention has been made with a view to solving such problems, and it is accordingly an object of the invention to provide a substrate drying device capable of securely removing a water droplet remaining on a substrate without increasing an air pressure.

A substrate drying device according to an aspect of the invention includes: a nozzle ejecting a fluid to a substrate to be processed, wherein the substrate is moved relative to the nozzle while the nozzle is spraying the fluid to dry the substrate, a parallel component to a surface of the substrate in an ejection direction of the fluid is inclined with respect to a moving direction in which the substrate moves relative to the nozzle, and an angle between the parallel component and the moving direction is changed at a changed portion in a predetermined position of the nozzles. Thus, it is possible to provide a substrate drying device capable of securely removing a water droplet remaining on a substrate without increasing an air pressure.

Here, an arrangement direction of the nozzles may be bent at the changed portion to change an angle between the arrangement direction of the nozzles and the moving direction to change the component of the ejection direction parallel to the surface of the substrate and the moving direction.

Further, the arrangement direction of the nozzles may be bent at the changed portion. Thus, it is possible to suppress a decrease in air pressure due to the change in ejection direction.

Further, the changed portion may be formed in a plurality of positions. The changed portion may be formed substantially throughout the nozzles. Thus, the air pressure may be decreased more evenly due to the change in ejection direction.

Furthermore, preferably, the substrate has a substantially rectangular shape, and in a state where the changed portion is formed above the substrate, and the nozzle is arranged above a side as a downstream side of the substrate in the moving direction and an adjacent side of the side on the downstream side, the fluid is sprayed such that an angle between the parallel component to a surface of the substrate in the ejection direction of the fluid from the nozzle above the side on the downstream side and the side on the downstream side of the substrate is smaller than an angle between the parallel component to a surface of the substrate in the ejection direction of the fluid from the nozzle above the adjacent side and the side on the downstream side of the substrate.

According to another aspect of the invention, a substrate processing method for moving a substrate to be processed with respect to a nozzle ejecting a fluid to process the substrate, includes: processing the substrate with a liquid; and spraying a fluid to the substrate from the nozzle and moving the nozzle and the substrate relative to each other to dry the substrate; the spraying the fluid includes: setting an angle between a parallel component to a surface of the substrate in an ejection direction of the fluid and a moving direction of the substrate relative to the nozzle; and drying the substrate by spraying the fluid from nozzle with a changing portion which is formed in a predetermined position of the nozzle and in which the angle between a parallel component and the moving direction is changed. It is accordingly possible to securely remove a water droplet remaining on a substrate without increasing an air pressure.

According to the present invention, it is possible to provide a substrate drying device and a substrate processing method capable of securely removing a water droplet remaining on a substrate without increasing an air pressure.

The above and other objects, features and advantages of the present invention will become more fully understood from the detailed description given hereinbelow and the accompanying drawings which are given by way of illustration only, and thus are not to be considered as limiting the present invention. BRIEF DESCRIPTION OF THE DRAWINGS

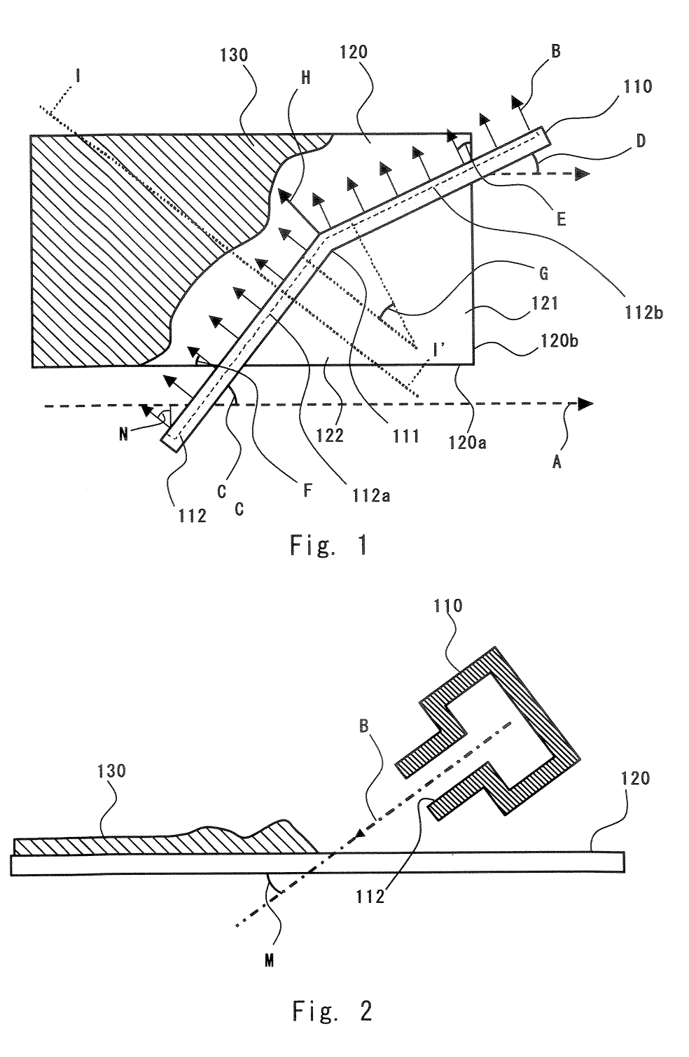

FIG. 1 is a top view of a substrate drying system according to a first embodiment of the present invention;

FIG. 2 is a sectional view of the substrate drying system according to the first embodiment of the present invention;

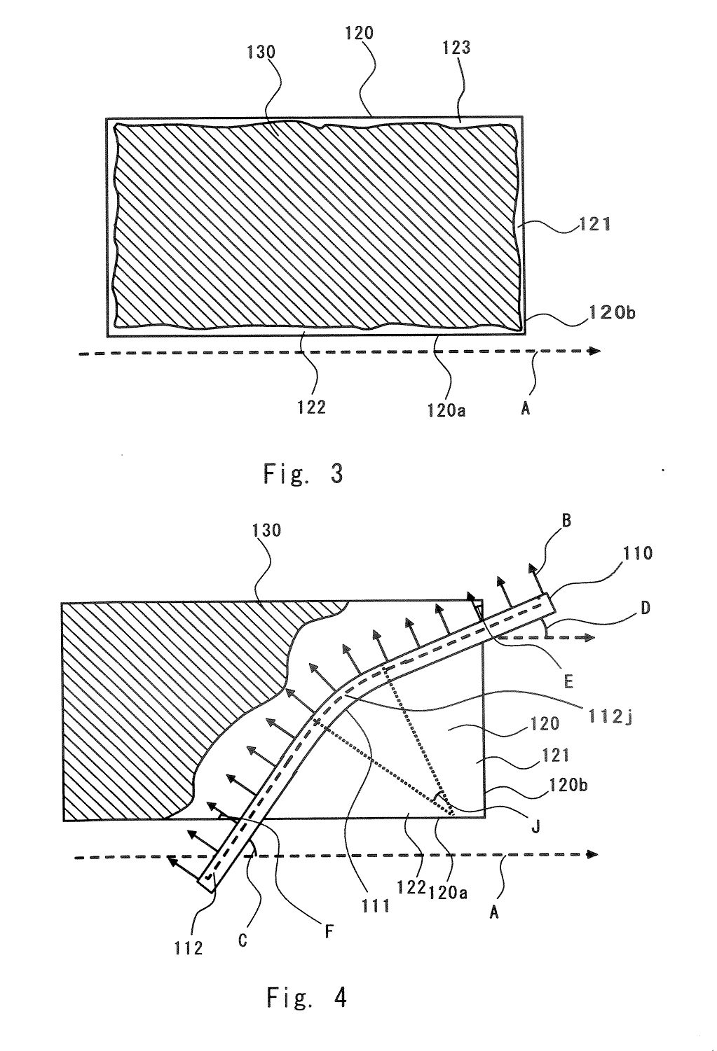

FIG. 3 is a top view of a substrate to be processed according to the first embodiment of the present invention;

FIG. 4 is a top view of a substrate drying system according to another embodiment of the present invention;

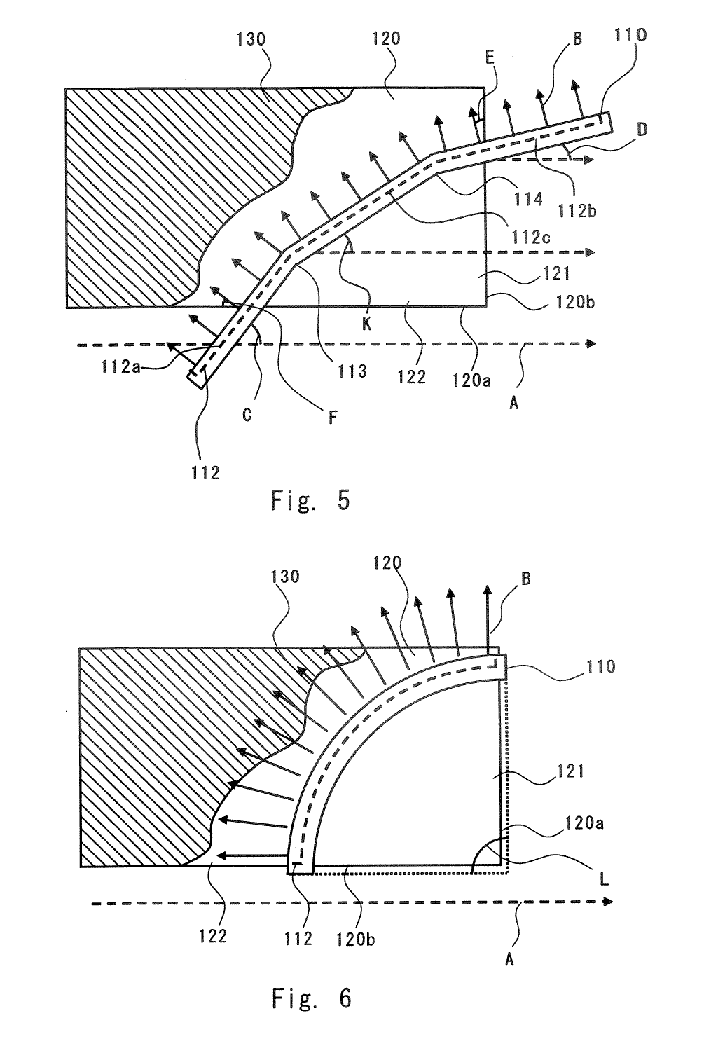

FIG. 5 is a top view of a substrate drying system according to another embodiment of the present invention;

FIG. 6 is a top view of a substrate drying system according to another embodiment of the present invention;

FIG. 7 is a top view of a conventional substrate drying system; and

FIG. 8 is a sectional view of the conventional substrate drying system.

### PREFERRED EMBODIMENT OF THE INVENTION

### First Embodiment

Hereinafter, an embodiment of the present invention is described below with reference to the accompanying drawings. The embodiment of the present invention is accomplished such that in a substrate drying device having an air knife drying system, an angle at which an air is sprayed from an air knife is changed, by which a dry gas is sprayed as in parallel to the substrate side as possible at the substrate end portion to thereby improve a drying efficiency to prevent a water droplet from remaining without draining off.

FIG. 1 is a top view of an air knife drying system in a substrate drying device according to the embodiment of the present invention. A substrate 120 to be dried has substantially square shape as shown in FIG. 1. In FIG. 1, the lower side and right side of the substrate 120 are referred to as a lower side 120a and a right side 120b. The substrate 120 is transferred with a transport roller or the like in a moving direction A as indicated by the arrow of FIG. 1. That is, the dashed line of FIG. 1 indicates the moving direction A of the substrate 120. Accordingly, the substrate 120 is fed from the left side to the right side in FIG. 1. The moving direction A of the substrate 120 is parallel to the lower side 120a of the substrate 120. Thus, the moving direction A is orthogonal to the right side 120b continuous from the lower side 120a of the substrate 120. Here, the right side 120b of the substrate 120 is positioned on the downstream side in the moving direction A of the substrate 120. That is, a dry gas is first sprayed from an air knife to the right side 120b on the downstream side of the substrate 120 in the moving direction A. Incidentally, the lower side 120a is an adjacent side of the right side 120b positioned on the downstream side in the moving direction A of the substrate 120.

An air knife 110 is placed on the substrate 120 surface. A dry gas is sprayed from an air nozzle of the air knife 110 in the direction of an arrow B in FIG. 1. The dry gas can blow off rinse water 130 applied to the substrate 120 surface. That is, while the air knife 110 is spraying the dry gas, the substrate 120 is transferred across an area where the air knife 110 sprays the dry gas. Hence, the dry gas is successively sprayed from the right end to the left end of the substrate 120. Then, the rinse water on the substrate 120 surface is brown away, and the entire surface of the substrate 120 can be dried. The rinse water 130 is, for example, pure water. Incidentally, the air knife 110 may be provided on both of upper and lower surfaces of the substrate 120.

The air knife 110 of this embodiment has a long and narrow shape as shown in FIG. 1, and is a bar-like or band-like member, for example. Slit-like opening is formed on the lower side of the air knife 110. This opening is air nozzle 112. The air nozzle 112 is arranged along the direction in which the air knife extends. The air nozzle 112 is formed over a longitudinal direction of the air knife 110. The dry gas is sprayed from the air nozzle 112 in the direction of the arrow B of FIG. 1. The air pressure is, for example, 0.8 MPa, but the air pressure may be 0.8 MPa or higher, or 0.8 MPa or lower. The air pressured needs to be high enough to blow off the rinse water 130, and is desirably set to such a pressure as can prevent the rinse water 130 from evaporating as mist. The dry gas is an air or an inert gas such as nitrogen gas.

FIG. 2 is a sectional view taken along the line I-I′ of FIG. 1. The air knife 110 is placed such that the air ejection direction as indicated by the arrow B of FIG. 2 is inclined at the angle M to the substrate 120 surface. The angle M is preferably as small as possible since the use efficiency and the drying efficiency of the dry gas can be improved.

As shown FIG. 1, the air knife 110 has a bending portion 111 as a changed portion around the center. The air knife 110 is bended by the angle G at the bending portion 111. Accordingly, the air knife 110 takes a dog-leg shape. The air nozzle 112 is arranged along the dog-leg shape of the air knife 110. Thus, the angle of the air nozzle 112 to the moving direction A of the substrate 120 is changed. The air nozzle 112 is provided in a dog-leg shape. The bending angle of the air nozzle 112 at the bending portion 111 is angle G. Here, a part of the nozzle 112 from the left end of the air knife 110 to the bending portion 111 are referred to as air nozzle 112a, and a part of the nozzle 112 from the right end of the air knife to the bending portion 111 are referred to as air nozzle 112b. The air nozzle 112a and the air nozzle 112b form an angle G therebetween. In other words, the air nozzle 112a and the air nozzle 112b that are inclined with each other cross at the bending portion 111.

In the plane parallel to the substrate surface, the ejection direction B of the dry gas from the air nozzle 112 is vertical to the arrangement direction of the air nozzle 112. Thus, a component of the dry gas ejection direction B parallel to the substrate surface is changed at the bending portion 111. Accordingly, an angle between the component of the dry gas ejection direction B parallel to the substrate surface and the moving direction A is changed at the midpoint of the air nozzle 112 (bending portion 111). That is, the ejection direction B of the air nozzle 112a and the ejection direction B of the air nozzle 112b form the angle G. The bending portion 111 may be set in an arbitrary position of the air nozzle 112.

Here, provided that an area where the air nozzle 112 sprays the dry gas is an ejection area, the ejection area shape corresponds to the shape of the air nozzle 112. Accordingly, the ejection area on the substrate 120 surface, that is, a dry gas spraying area has a dog-leg shape similarly to the shape of the air nozzle 112. The substrate 120 crosses the ejection area to thereby execute the drying process of the substrate 120. The ejection area is formed throughout entire substrate in the direction parallel to the short side of the substrate 120, that is, in the direction vertical to the moving direction A as substrate transferring direction. In other words, the ejection area is set to have the length larger than the substrate 120 width, that is, the length of the right side 120b if projected in the direction vertical to the substrate surface, that is, to the plane parallel to the substrate 120.

As shown in FIG. 1, the air nozzle 112a of the air knife 110 is arranged at the angle C to the moving direction A of the substrate 120. The air nozzle 112b of the air knife 110 is arranged at the angle D to the moving direction A of the substrate 120. Incidentally, the angle C and the angle D as the angle between the moving direction A and the arrangement direction of the air nozzle 112 are 90° or smaller. Here, the angle G of the bending portion 111 is set such that the angle D is smaller than the angle C. As a result, the dry gas ejection direction B at ends 121 and 122 of the substrate 120 can be closer to the side of the substrate 120. That is, an angle F between the lower side 120a of the substrate 120 and the ejection direction B of the dry gas from the air nozzle 112a above the lower side 120a can be made smaller, and an angle E between the right side 120b of the substrate and the ejection direction B of the dry gas from the air nozzle 112b above the right side 120b can be made smaller. If an angle between the ejection direction B of the dry gas from the air nozzle 112a and the right side 120b is an angle N, the bending portion 111 is provided, so the angle E is smaller than the angle N.

Detailed description thereof is described below. In the plane parallel to the substrate surface, the air knife 110 is inclined with respect to the moving direction A of the substrate 120. Accordingly, the air nozzle 112a is provided on the upstream side of the air nozzle 112b in the moving direction A of the substrate 120. The air nozzle 112a out of the air nozzle 112 is arranged on the upstream side in the moving direction A of the substrate 120, and the air nozzle 112b is arranged on the downstream side in the moving direction A of the substrate. The bending portion 111 is formed, so an angle between the arrangement direction of the air nozzle 112 and the moving direction A of the substrate 120 is different between the upstream side and the downstream side of the bending portion 111. As shown in FIG. 1, the angle of the upstream side, that is, the angle between the air nozzle 112a and the moving direction A is the angle C. The angle of the downstream side, that is, the angle between the air nozzle 112b and the moving direction A is the angle D. Here, a difference between the angle C and the angle D corresponds to the angle G.

The moving direction A is parallel to the lower side 120a of the substrate 120, so the angle between the lower side 120a of the substrate 120 and the air nozzle 112a is the angle C. Further, the angle between the lower side 120a of the substrate 120 and the air nozzle 112b is the angle D.

Consider such a state that the air nozzle 112a is arranged above the lower side 120a of the substrate 120, and the air nozzle 112b is arranged above the right side 120b continuous from the lower side 120a of the substrate 120 as shown in FIG. 1. That is, consider such a state that the air nozzle 112a is arranged across the lower side 120a, and the air nozzle 112b is arranged across the right side 120b as the downstream side. In this state, the bending portion 111 is positioned above the substrate 120.

An angle between the lower side 120a of the substrate 120 and the air nozzle 112a above the lower side 120a of the substrate 120 is an angle C. An angle between the lower side 120a with the air nozzle 112a and the air nozzle 112b arranged above the right side 120b is an angle D. Here, the angle G is set such that the angle C is smaller than the angle D. Thus, an angle F between the lower side 120a of the substrate 120 and the ejection direction B of the air nozzle 112a above the lower side 120a can be made smaller. As a result, at the substrate end 122 near the lower side 120a, the component of the ejection direction B parallel to the substrate surface can get close to parallel to the lower side 120a. Further, the angle E between the right side 120b of the substrate 120 and the ejection direction B of the air nozzle 112b above the right side 120b can be made smaller. Thus, at the substrate end 121 near the right side 120b, the component of the ejection direction B parallel to the substrate surface can get close to parallel to the right side 120b.

In the present invention, the bending portion 111 for changing the component of the ejection direction B parallel to the substrate surface is provided at the midpoint of the air nozzle 112. Thus, a dry gas ejection direction adequate for not only the right side 120b as the downstream side of the substrate 120 but also the lower side 120a continuous from the right side 120b can be realized. Accordingly, it is possible to reliably dry the substrate 120. In this way, the ejection direction at the substrate end gets close to parallel to the substrate side, by which the rinse water 130 at the substrate end can be efficiently dried.

The reason why the ejection direction B at the substrate ends 121 and 122 gets close to parallel to the sides 120a and 120b to thereby efficiency dry the rinse water 130 is described in brief. In some cases, in a step of rinsing the substrate 120 with the rinse water 130, the rinse water 130 cannot sufficiently the substrate ends 121 and 122. In this case, as shown in FIG. 3, the substrate ends 121 and 122 are exposed portion 123 not covered with the rinse water 130. That is, the exposed portion 123 is dried and exposed to the atmosphere. Therefore, the exposed portion 123 is highly hydrophilic. As a result, the substrate ends 121 and122 are hardly dried with the air knife 110, and water droplets tend to remain there.

Further, on the downstream side of the substrate 120, the rinse water 130 near the right side 120b is moved from the right side 120b to the substrate center by spraying the dry gas. That is, the dry gas is sprayed from the outer side to the inner side of the substrate 120 near the right side 120b on the downstream side in the moving direction A of the substrate 120. Then, the substrate end 121 is highly hydrophilic for the above reason, so the substrate end near the right side 120b is more difficult to dry.

Moreover, also at the substrate end 122, the dry gas is sprayed from the air nozzle 112a from the outer side to the inner side of the substrate 120. Thus, as in the portion around the right side 120b, the substrate end 122 is difficult to dry. That is, the substrate ends 122 and 121 around the lower side 120a and the right side 120b are less dried than the substrate ends around the upper side and the left side.

In the present invention, the bending portion 111 is formed, by which the component of the ejection direction B of the air nozzle 112b parallel to the substrate surface gets close to parallel to the right side 120b. That is, the angle E is decreased. Hence, the rinse water 130 left around the substrate end 121 is moved along the right side 120b of the substrate 120. Accordingly, it is possible to prevent the rinse water from moving to the substrate center from the substrate end 121, and the substrate can be surely dried. Furthermore, the component of the ejection direction B of the air nozzle 112a parallel to the substrate surface gets close to parallel to the lower side 120a. That is, the angle F is decreased. Thus, the rinse water 130 remaining around the substrate end 122 is moved along the lower side 120a of the substrate 120. Accordingly, it is possible to prevent the rinse water 130 from moving from the substrate end 122 to the substrate center, and the substrate 120 can be surely dried. Thus, the substrate ends 121 and 122 where water droplets tend to remain can be efficiently dried.

Further, in the state as shown in FIG. 1, the angle D between the air nozzle 112b and the lower side 120a is smaller than 450. Hence, the dry gas can be sprayed at the angle E that makes the ejection direction parallel to the right side 120b. Further, the angle C between the air nozzle 112a and the lower side 120a is made larger than 450. As a result, the dry gas can be sprayed at the angle F that is close to parallel to the lower side 120a. The direction of the air nozzle 112 is changed in this way, so the dry gas ejection direction B around a corner portion where the lower side 120a crosses the right side 120b can get close to parallel to the lower side 120a. That is, the ejection direction B at the substrate end 121 near the lower side 120a of the substrate 120 can get close to parallel to the lower side 120a.

The air knife 110 is arranged/formed such that the angle D on the downstream side is smaller than the angle C on the upstream side, by which the angle E between the dry gas ejection direction B of the substrate 120 and the lower side 120a of the substrate 120, and the angle F between the dry gas ejection direction B of the substrate 120 and the right side 120b can be decreased. Thus, the dry gas ejection angles at the substrate ends 121 and 122 are set to be close to parallel to the substrate side. Incidentally, the angle C preferably ranges from 45° to 60°.

Here, if the angle G of the bending portion 111 is too large, the angle D is too small. For example, if the angle D is 0°, the air knife 110 cannot pass through the entire substrate end 121. The air knife 110 passes through only the substrate end 121 from the substrate end 122 side to the bending portion. In this case, the dry gas is not sufficiently sprayed in some portions of the substrate 120 surface. This is undesirable. Accordingly, as shown in FIG. 1, when the air nozzle 112a on the upstream side is moved above the lower side 120a of the substrate 120, the air nozzle 112 is gradually closer to the upper side opposite to the lower side 120a of the substrate, from the upstream side to the downstream side. That is, the angle G is set such that the air nozzle 112 formed on the right side (downstream side) is positioned on the upper side.

Further, if the angle G is too large, the angle of the ejection direction B is abruptly changed around the bending portion 111, and the air ejection pressure in the direction of an arrow H of FIG. 1 is lowered. In this case, the rinse water 130 cannot be sufficiently drained off at the bending portion 111. Thus, the angle G of the bending portion 111 is determined based on the relation between the angle C and the angle D, and is preferably 15° to 60°.

In this structure, the substrate 120 is transferred in the moving direction A of FIG. 1 while the air knife 110 is spraying the dry gas to the substrate 120 surface in the arrow B direction. Furthermore, a parallel component to the surface of the substrate 120 in the dry gas ejection direction B is inclined with respect to a moving direction A. The angle between the parallel component and the moving direction A is changed at the changed portion in the predetermined position of the nozzle 110. As a result, the rinse water 130 on the substrate 120 surface can be removed.

With the above structure, a drying process can be executed without increasing a dry gas pressure, and it is possible to suppress a splash of the rinse water 130 due to the application of the dry gas and suppress the generation of mist. Further, a consumed amount of dry gas can be reduced, and a running cost of the drying step can be saved. Accordingly, the substrate 120 can be efficiently dried.

As described above, according to the first embodiment of the present invention, it is possible to a substrate drying device and a substrate drying method that can preferably remove water droplets remaining on the substrate without increasing an air pressure.

Incidentally, in the above description, an example of spraying a gas from the air knife 110 is demonstrated, but it is possible to spray a volatile liquid, for example, to blow off the rinse water 130. That is, a liquid and such other fluid may be used for drying the substrate 120 in place of the gas. Further, the pure water is used as the rinse water 130 in the above description, but the rinse water may be, for example, an etchant, a washing solution, a chemical solution, and other such liquids. The substrate moving direction is not limited to a direction parallel to the substrate side but may be inclined to the substrate side. Moreover, the air knife, not the substrate, may be moved.

### Second Embodiment

Referring to FIG. 4, a second embodiment of the present invention is described. Hence explanations of portions similar to first embodiment are omitted. The air knife 110 of FIG. 4 is curved with a predetermined radius of curvature in the bending portion 111. Further, the air knife 110 is curved over the angle J in the bending portion 111. Accordingly, the angle of the air nozzle 112 can be changed. Thus, a component of the ejection direction B parallel to the substrate surface is changed to decrease the angles E and F at the substrate ends 121 and 122.

In the embodiment of FIG. 4, air nozzle 112j in the bending portion 111 is curved over the angle J. That is, instead of changing the angle at one point as shown in FIG. 1, the angle of the air knife 110 is changed in the range of the angle J as shown in FIG. 4. Thus, a decrease of the dry gas ejection pressure in the direction of an arrow H of FIG. 1 can be dispersed evenly over the angle J. Thus, it is possible to suppress a decrease in air ejection pressure in the bending portion 111. The angle J is set such that the angle D is smaller than the angle C in FIG. 4.

### Third Embodiment

Referring to FIG. 5, a third embodiment of the present invention is described. Hence explanations of portions similar to first embodiment are omitted. The air knife 110 of FIG. 5 changes its angle at two positions, bending portions 113 and 114. That is, air nozzle 112c is arranged between the upstream-side air nozzle 112a and the downstream-side air nozzle 112b. Here, provided that an angle between the air nozzle 112c and the moving direction A is K, the relation among the angles C, K, and D is C>K>D. That is, the air nozzle 112 is gradually closer to the upper side opposite to the lower side 120a of the substrate, from the upstream side to the downstream side. The air knife 110 of FIG. 5 changes its angle at two positions, bending portions 113 and 114, not at one position as shown in FIG. 1. Thus, the dry gas ejection direction B is changed at two positions, the bending portions 113 and 114, and the decrease in air ejection pressure at the bending portions can be suppressed.

A feature of this embodiment is to change the angle of the air knife 110 at plural positions. The number of positions is not limited to two as shown in FIG. 5, but may be three or more. Thus, the angle of the air knife 110 is changed more largely than the case of changing the angle at one position. Further, the angles E and F can be more decreased. Further, plural bent (curved) portions 111 as shown in FIG. 4 may be formed as changed portions. Alternatively, the bent portions and the curved portions may be both formed.

### Fourth Embodiment

Referring to FIG. 6, a fourth embodiment of the present invention is described. Hence explanations of portions similar to first embodiment are omitted. The whole air knife 110 of FIG. 6 is curved with a predetermined radius of curvature over the angle L. The whole air knife 110 is changed instead of changing the angle only in the bending portion 111 as shown in FIG. 4. Thus, the air ejection direction B is changed evenly throughout the air knife 110 in accordance with the curved form, and the decrease in air ejection pressure can be suppressed. The angle L is, for example, 90°. With this structure, the dry air ejection direction B can be made substantially parallel to the substrate sides at the substrate ends 121 and 122.

As shown in FIG. 6, the end portion of the air nozzle 112 on the upper side of the substrate 120 is positioned at the substrate end. As a result, the dry gas can be sprayed to the end portions around the upper side of the substrate as well. Further, it is possible to spray the dry gas from the inner side to the outer side of the substrate, around the upper side of the substrate. Hence, moisture around the upper side of the substrate 120 can be efficiently dried.

Incidentally, in the modes described in the above embodiments, the air knife is provided with the bending portions to change the dry gas ejection direction. However, instead of changing the air knife itself, the ejection direction of the air nozzle of the air knife is changed to thereby obtain beneficial effects similar to the above embodiments. Further, this is effective for the drying step in a manufacturing process of a semiconductor or liquid crystal display device. Further, the present invention is applicable to removal of liquids such as an etchant as well as the rinse water.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A substrate drying device, comprising:
a nozzle ejecting a fluid to a substrate to be processed,
wherein the substrate is moved relative to the nozzle while the nozzle is spraying the fluid to dry the substrate,
a parallel component to a surface of the substrate in an ejection direction of the fluid is inclined with respect to a moving direction in which the substrate moves relative to the nozzle, and
an angle between the parallel component and the moving direction is changed at a changed portion in a predetermined position of the nozzle.

2. The substrate drying device according to claim 1, wherein an arrangement direction of the nozzle is bent at the changed portion to change an angle between the arrangement direction of the nozzle and the moving direction to change the component of the ejection direction parallel to the surface of the substrate and the moving direction.

3. The substrate drying device according to claim 1, wherein the arrangement direction of the nozzle is bent at the changed portion.

4. The substrate drying device according to claim 2, wherein the arrangement direction of the nozzle is bent at the changed portion.

5. The substrate drying device according to claim 1, wherein the changed portion is formed in a plurality of positions.

6. The substrate drying device according to claim 2, wherein the changed portion is formed in a plurality of positions.

7. The substrate drying device according to claim 3, wherein the changed portion is formed in a plurality of positions.

8. The substrate drying device according to claim 4, wherein the changed portion is formed in a plurality of positions.

9. The substrate drying device according to claim 3, wherein the changed portion is formed substantially throughout the nozzle.

10. The substrate drying device according to claim 4, wherein the changed portion is formed substantially throughout the nozzle.

11. The substrate drying device according to claim 1, wherein the substrate has a substantially rectangular shape, and
in a state where the changed portion is formed above the substrate, and the nozzle is arranged above a side as a downstream side of the substrate in the moving direction and an adjacent side of the side on the downstream side,
the fluid is sprayed such that an angle between the parallel component to a surface of the substrate in the ejection direction of the fluid from the nozzle above the side on the downstream side and the side on the downstream side of the substrate is smaller than an angle between the parallel component to a surface of the substrate in the ejection direction of the fluid from the nozzle above the adjacent side and the side on the downstream side of the substrate.

12. The substrate drying device according to claim 2, wherein the substrate has a substantially rectangular shape, and
in a state where the changed portion is formed above the substrate, and the nozzle is arranged above a side as a downstream side of the substrate in the moving direction and a adjacent side of the side on the downstream side,
the fluid is sprayed such that an angle between the parallel component to a surface of the substrate in the ejection direction of the fluid from the nozzle above the side on the downstream side and the side on the downstream side of the substrate is smaller than an angle between the parallel component to a surface of the substrate in the ejection direction of the fluid from the nozzle above the adjacent side and the side on the downstream side of the substrate.

13. The substrate drying device according to claim 3, wherein the substrate has a substantially rectangular shape, and
in a state where the changed portion is formed above the substrate, and the nozzle is arranged above a side as a downstream side of the substrate in the moving direction and a adjacent side of the side on the downstream side,
the fluid is sprayed such that an angle between the parallel component to a surface of the substrate in the ejection direction of the fluid from the nozzle above the side on the downstream side and the side on the downstream side of the substrate is smaller than an angle between the parallel component to a surface of the substrate in the ejection direction of the fluid from the nozzle above the adjacent side and the side on the downstream side of the substrate.

14. The substrate drying device according to claim 4, wherein the substrate has a substantially rectangular shape, and
in a state where the changed portion is formed above the substrate, and the nozzle is arranged above a side as a downstream side of the substrate in the moving direction and a adjacent side of the side on the downstream side,
the fluid is sprayed such that an angle between the parallel component to a surface of the substrate in the ejection direction of the fluid from the nozzle above the side on the downstream side and the side on the downstream side of the substrate is smaller than an angle between the parallel component to a surface of the substrate in the ejection direction of the fluid from the nozzle above the adjacent side and the side on the downstream side of the substrate.

15. A substrate processing method for moving a substrate to be processed with respect to a nozzle ejecting a fluid to process the substrate, comprising:
processing the substrate with a liquid; and
spraying a fluid to the substrate from the nozzle and moving the nozzle and the substrate relative to each other to dry the substrate;
the spraying the fluid includes:
setting an angle between a parallel component to a surface of the substrate in an ejection direction of the fluid and a moving direction of the substrate relative to the nozzle; and
drying the substrate by spraying the fluid from nozzle with a changing portion which is formed in a predetermined position of the nozzle and in which the angle between a parallel component and the moving direction is changed.
